(19) United States
(12) Patent Application Publication
(10) Pub. No.: US 2025/0316503 A1
(43) Pub. Date: Oct. 9, 2025

(54) FILTER APPARATUS FOR SUBSTRATE TREATMENT APPARATUS AND CLEAN AIR SUPPLY METHOD

(71) Applicant: Tokyo Electron Limited, Tokyo (JP)

(72) Inventors: Ryo SEGUCHI, Koshi City (JP); Masashi TSUCHIYAMA, Koshi City (JP); Naoki TAJIMA, Koshi City (JP); Shogo INABA, Koshi City (JP)

(21) Appl. No.: 19/091,034

(22) Filed: Mar. 26, 2025

(30) Foreign Application Priority Data
Apr. 5, 2024 (JP) 2024-061224

(51) Int. Cl. H01L 21/67; B01D 46/00; B01D 46/44

(52) U.S. Cl. CPC H01L 21/67017; B01D 46/0043; B01D 46/444; B01D 46/448

(57) ABSTRACT

A filter apparatus having a filter installed above a plurality of substrate treatment apparatuses arranged in a row, includes: an air inlet formed on one end portion side in a row direction of the substrate treatment apparatuses in a duct space formed above the filter; and an air volume adjustment mechanism configured to variably adjust a volume of air flowing from a first space on the air inlet side in the duct space into a second space adjacent to the first space in the row direction, the air volume adjustment mechanism being provided at a position between apparatuses in the plurality of substrate treatment apparatuses in plan view.

### CROSS REFERENCE TO RELATED APPLICATIONS

This application is based upon and claims the benefit of priority of the prior Japanese Patent Application No. 2024-61224, filed in Japan on Apr. 5, 2024, the entire contents of which are incorporated herein by reference.

### TECHNICAL FIELD

This disclosure relates to a filter apparatus for a substrate treatment apparatus and a clean air supply method.

### BACKGROUND

Japanese Patent Application No. 2010-87115 discloses a substrate processing apparatus having an application processing part. Application processing rooms are hierarchically installed in the application processing part. In each application processing room, an application processing unit is provided. Further, in each application processing room, an air supply unit is provided. Air subjected to temperature and humidity adjustment is supplied from the air supply unit.

### SUMMARY

An aspect of this disclosure is a filter apparatus having a filter installed above a plurality of substrate treatment apparatuses arranged in a row, the filter apparatus including: an air inlet formed on one end portion side in a row direction of the substrate treatment apparatuses in a duct space formed above the filter; and an air volume adjustment mechanism configured to variably adjust a volume of air flowing from a first space on the air inlet side in the duct space into a second space adjacent to the first space in the row direction, the air volume adjustment mechanism being provided at a position between apparatuses in the plurality of substrate treatment apparatuses in plan view.

### BRIEF DESCRIPTION OF THE DRAWINGS

FIG. 1 is an explanatory view schematically illustrating the configuration on a front surface side of a coating and developing apparatus as a substrate treatment system in which a filter apparatus according to this embodiment is installed.

FIG. 2 is a top view illustrating an interior of a solution treatment module.

FIG. 3 is a cross-sectional view on the front surface side of the filter apparatus.

FIG. 4 is a top view of a duct member in a state where an adjustment mechanism is attached.

FIG. 5 is a perspective view illustrating a partition member.

FIG. 6 is a perspective view illustrating a flow part.

FIG. 7 is a cross-sectional view of an air volume adjustment mechanism.

FIG. 8 is a view illustrating a control example of the filter apparatus.

FIG. 9 is a view illustrating a control example of the filter apparatus.

FIG. 10 is a view illustrating a control example of the filter apparatus.

FIG. 11 is a top view for explaining another example of a damper of the air volume adjustment mechanism.

FIG. 12 is a perspective view for explaining another example of the partition member.

FIG. 13 is a cross-sectional view for explaining another example of the air volume adjustment mechanism.

FIG. 14 is an explanatory view illustrating another example of the arrangement of an air volume sensor.

FIG. 15 is an explanatory view illustrating another example of the arrangement of the air volume sensor.

FIG. 16 is an explanatory view illustrating another example of the solution treatment module.

FIG. 17 is an explanatory view illustrating an example of a measurement wafer.

FIG. 18 is an explanatory view illustrating another example of the coating and developing apparatus.

### DETAILED DESCRIPTION

In a photolithography process in a manufacturing process of a semiconductor device or the like, a resist pattern is formed on a semiconductor wafer (hereinafter, referred to as a “wafer”) as a substrate.

To form this resist pattern, the wafer is transferred, for example, to a coating and developing apparatus which performs coating and development of the resist and subjected to a solution treatment of the resist, then transferred to an exposure apparatus and exposed with a desired pattern, and then subjected to a developing treatment and thereby formed with a resist pattern.

To various substrate treatment apparatuses installed in the coating and developing apparatus, clean air adjusted in temperature and humidity is supplied. For example, to a resist coating apparatus which applies the resist, clean air at predetermined temperature and humidity is supplied by a downflow from above via a filter apparatus. This is because changes in the temperature and humidity affect the thickness of the coating film of the resist.

The supply of the clean air to the filter apparatus is performed, for example, from an air conditioner provided outside the coating and developing apparatus via a duct (hereinafter, referred to as a “vertical duct”) laid in the vertical direction. When the clean air is supplied from the filter apparatus to the various substrate treatment apparatuses, the clean air is made to flow from the vertical duct into a duct space extending in the horizontal direction via an intake port at one end portion of various substrate treatment modules housing the substrate treatment apparatuses in the filter apparatus. Then, the filter apparatus supplies the clean air in the duct space by the downflow to each substrate treatment apparatus below the filter via a filter arranged below the duct space.

Incidentally, recently, a plurality of substrate treatment apparatuses may be installed in one substrate treatment module surrounded by a casing. For example, two solution treatment apparatuses may be arranged in a row in one casing in the solution treatment module. Each solution treatment apparatus has a cup open at an upper portion in a manner to surround a spin chuck which holds and rotates the substrate. To the cup of each solution treatment apparatus, the clean air adjusted in temperature and humidity is supplied by the downflow from the filter apparatus located above the cup.

In the configuration in which the plurality of substrate treatment apparatuses are arranged in the one casing as above, the filter apparatus may be made common between the substrate treatment apparatuses in the casing. In this case, desired treatment results cannot be obtained in both the substrate treatment apparatus close to the vertical duct and the substrate treatment apparatus far from the vertical duct in some cases. Specifically, for example, when the substrate treatment apparatus is the coating apparatus of the resist changing in thickness of the coating film according to the flow velocity of the downflow, the flow velocity of the downflow to which the substrate being a treatment object is exposed is different between the coating apparatus close to the vertical duct and the coating apparatus far from the vertical duct due to variation during manufacture, and a resist film with a desired thickness cannot be formed on the substrate in at least any one of the coating apparatuses in some cases.

Hence, the technique according to this disclosure adjusts the difference in treatment results between substrate treatment apparatuses in a case where a plurality of substrate treatment apparatuses are arranged in a row and clean air is supplied to each substrate treatment apparatus from a filter apparatus common between the substrate treatment apparatuses.

The configurations of a filter apparatus for a substrate treatment apparatus and a substrate treatment system according to this embodiment will be explained below with reference to the drawings. Note that, in the description, the same signs denote components having substantially the same functional configurations to omit redundant explanation thereof.

### Coating and Developing Apparatus

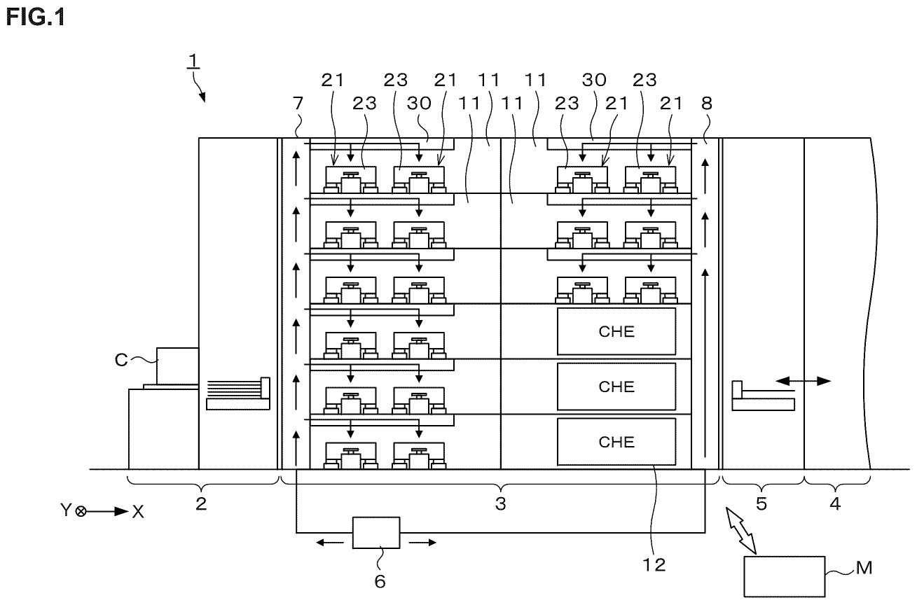

FIG. 1 is an explanatory view schematically illustrating the configuration on a front surface side of a coating and developing apparatus as a substrate treatment system in which a filter apparatus according to this embodiment is installed.

A coating and developing apparatus 1 in FIG. 1 has a configuration

in which a carrier block 2 into/out of which a carrier C housing a plurality of wafers as substrates is carried, a treatment block 3 which includes various substrate treatment apparatuses each performing a predetermined treatment on the wafer, and an interface block 5 which delivers the wafer W to/from an exposure processing apparatus 4 are integrally connected.

In the treatment block 3, solution treatment modules 11 are installed in multiple stages. Each solution treatment module 11 is demarcated by a casing and has a solution treatment apparatus as a substrate treatment apparatus in the casing. Further, in the treatment block 3, thermal treatment modules (not illustrated) are installed in multiple stages. Each thermal treatment module is demarcated by a casing and has a thermal treatment apparatus as a substrate treatment apparatus in each casing. Further, in the treatment block 3, so-called chemical boxes 12 are provided which store, in exchangeable tanks, various treatment solutions to be supplied to the solution treatment modules 11.

In the above coating and developing apparatus 1, at least one control unit M is provided. The control unit M processes computer-executable instructions causing the coating and developing apparatus 1 to perform various steps explained in this disclosure. The control unit M can be configured to control components of the coating and developing apparatus 1 so as to execute the various steps explained herein. In one embodiment, part or all of the control unit M may be included in the coating and developing apparatus 1. The control unit M may include a processor, a storage, and a communication interface. The control unit M is implemented, for example, by a computer. The processor can be configured to read from the storage a program which provides a logic or routine enabling performance of various control operations and execute the read program to thereby perform various control operations. This program may be stored in the storage in advance, or acquired via a medium when required. The acquired program is stored in the storage, and read out of the storage and executed by the processor. The medium may be various computer-readable storage media or may be a communication line connected to the communication interface. The storage medium may be a transitory one or a non-transitory one. The processor may be a CPU (Central Processing Unit), or may be one or a plurality of circuits. The storage may include a RAM (Random Access Memory), a ROM (Read Only Memory), an HDD (Hard Disk Drive), an SSD (Solid State Drive), or a combination of them. The communication interface may communicate with the coating and developing apparatus 1 via a communication line such as a LAN (Local Area Network).

The control unit M functions also as a control unit for a later-explained filter apparatus 30.

### Solution Treatment Module 11

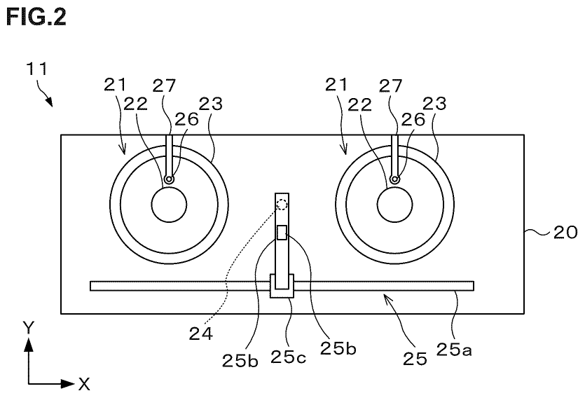

Next, a solution treatment module 11 will be explained referring to FIG. 1 and using FIG. 2. FIG. 2 is a top view illustrating an interior of the solution treatment module 11.

In one solution treatment module 11, a plurality of (two in the example of the drawing) solution treatment apparatuses 21 are arranged in a row in a casing 20 as illustrated in FIG. 2. Hereinafter, a row direction (X-direction in the drawing) of the solution treatment apparatuses 21 may be called an apparatus width direction, and a direction (Y-direction in the drawing) orthogonal to the apparatus width direction within a horizontal plane may be called a depth direction.

Each solution treatment apparatus 21 is an apparatus which performs a treatment using a treatment solution on the wafer, and is concretely, for example, a coating apparatus which forms various coating films including a coating film of resist. Each solution treatment apparatus 21 may be a solution treatment apparatus other than the coating apparatus, such as a developing apparatus which develops the wafer using a developing solution as the treatment solution.

The plurality of solution treatment apparatuses 21 of one solution treatment module 11 have the same configuration.

Each solution treatment apparatus 21 has a spin chuck 22 and a cup 23. The spin chuck 22 holds and rotates the wafer. The cup 23 houses the wafer in a manner to prevent the treatment solution (concretely, resist or the like) from the wafer on the spin chuck 22 from scattering to the surroundings, and has an upper surface open.

Further, in the casing 20, a nozzle 24 which discharges the treatment solution (concretely, resist or the like) to the wafer held on the spin chuck 22 and a moving mechanism 25 which moves the nozzle 24 in the horizontal direction are provided. In this embodiment, the nozzle 24 and the moving mechanism 25 are shared between the plurality of solution treatment apparatuses 21.

The moving mechanism 25 has a rail 25a, an arm 25b, and a drive mechanism 25c.

The rail 25a is provided in a manner to extend along the apparatus width direction (X-direction in FIG. 2) on one side (Y-direction negative side in FIG. 2) in the depth direction of the cup 23. The rail 25a is formed from the outside on one side (X-direction negative side in FIG. 2) in the apparatus width direction of the cups 23 of the plurality of solution treatment apparatuses 21 to the outside on the other side (X-direction positive side in FIG. 2) in the apparatus width direction.

The arm 25b is provided on the rail 25a and is movable on the rail 25a by the drive mechanism 25c. The drive mechanism 25c has a drive source (not illustrated) such as a motor which generates a driving force for moving the arm 25b along the rail 25a. The arm 25b moving on the rail 25a by the drive mechanism 25c enables the nozzle 24 to move from a waiting section (not illustrated) provided between the cups 23 of the plurality of solution treatment apparatuses 21 to above the wafer in the cup 23. The drive mechanism 25c may be also provided with a drive source (not illustrated) which generates a driving force for raising and lowering the arm 25b.

Further, above the solution treatment apparatuses 21 in the solution treatment module 11 (concretely, inside the casing 20), the filter apparatus 30 is arranged as illustrated in FIG. 1.

Air adjusted to predetermined temperature and humidity, for example, 23° C. and 45% RH is supplied from an air conditioner 6 provided outside the coating and developing apparatus 1 to each filter apparatus 30 such that the air is supplied from ducts 7, 8 laid in the vertical direction in the coating and developing apparatus 1 to the filter apparatus 30 of each solution treatment module 11.

Further, in the solution treatment module 11, an air volume sensor 26 is provided as illustrated in FIG. 2. Specifically, the air volume sensor 26 is provided, for example, for each solution treatment apparatus 21, and is arranged between the cup 23 and the filter apparatus 30 in the casing 20. Further, the air volume sensor 26 is supported and fixed, for example, at a wall on one side in the depth direction, namely, the back surface side in the casing 20, via a support member 27.

### Filter Apparatus

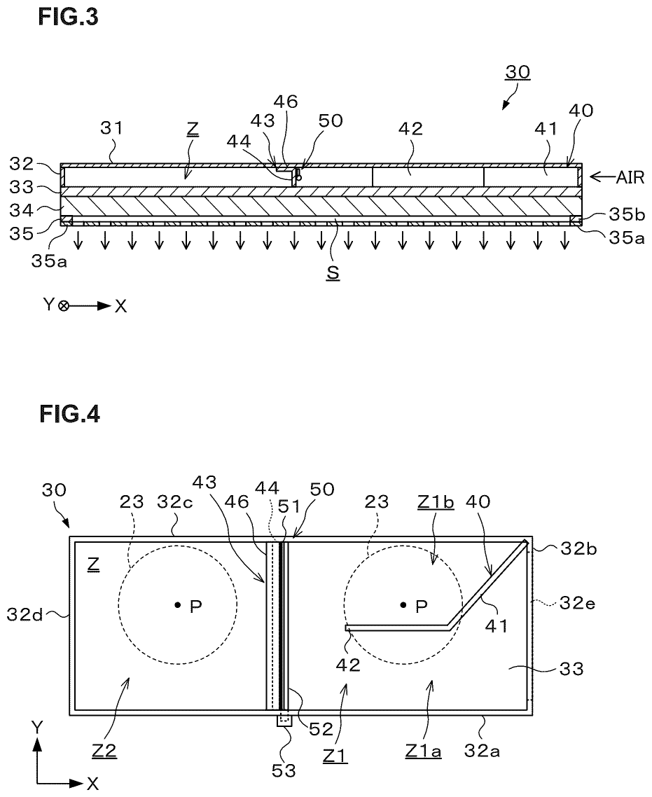

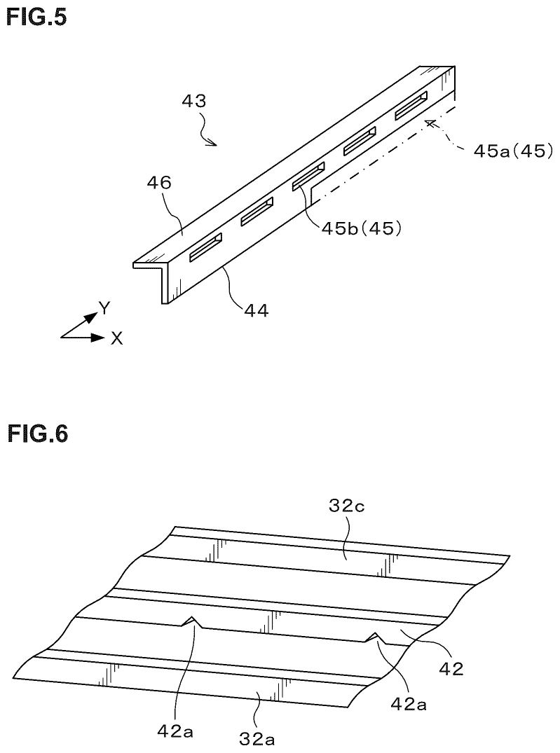

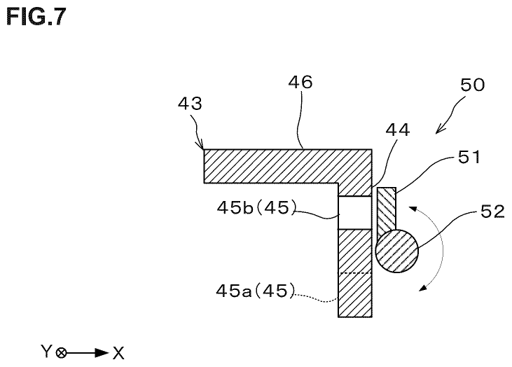

Next, the filter apparatus 30 will be explained using FIG. 3 to FIG. 7. FIG. 3 is a cross-sectional view on the front surface side of the filter apparatus 30. FIG. 4 is a top view of a later-explained duct member in a state where a later-explained adjustment mechanism is attached. FIG. 5 is a perspective view illustrating a later-explained partition member. FIG. 6 is a perspective view illustrating a later-explained flow part. FIG. 7 is a cross-sectional view of a later-explained air volume adjustment mechanism.

The filter apparatus 30 has a top plate 31, a duct member 32, a nonwoven fabric 33, a filter 34, and a rectifier plate 35 as illustrated in FIG. 3, and they are stacked in this order from the top. A space surrounded by the top plate 31, the duct member 32, and the nonwoven fabric 33 constitute a duct space Z.

The duct member 32 opens at the top face and the bottom face, and has a rectangular frame structure surrounded at four faces by a front wall 32a, a side wall 32b on the apparatus width direction one end portion side (X-direction positive side in the drawing), a back wall 32c, and a side wall 32d on the apparatus width direction other end portion side (X-direction negative side in the drawing) as illustrated in FIG. 4. The side wall 32b is formed with an air inlet 32e, and the air inlet 32e is connected to the already-explained duct 7 or duct 8 so that the air adjusted in temperature and humidity from the ducts 7, 8 is taken into the air inlet 32e.

The duct member 32 has an airflow guide member 40 which vertically partitions the duct space Z. This airflow guide member 40 has an introduction part 41 which diagonally continues from the end portion on the back surface side (Y-direction positive side in the drawing) of the air inlet 32e toward the front surface side (Y-direction negative side in the drawing), and a guide part 42 continuous from the introduction part 41 and changing in angle in plan view to extend parallel to the front wall 32a and the back wall 32c. Note that the airflow guide member 40 may be omitted.

Between a terminal end portion of the guide part 42 and the side wall 32d on the other end portion side, a partition member 43 is provided. The partition member 43 has a partition plate 44. The partition plate 44 is a plate-shaped member which vertically partitions at least an upper portion of the duct space Z and is arranged in parallel to the side wall 32b. The partition plate 44 separates a first space Z1 on one end portion side in the duct space Z and a second space Z2 on the other end portion side. Further, a front surface side (Y-direction negative side in the drawing) of the airflow guide member 40 in the first space Z1 constitutes a front space Z1a, and a back surface side (Y-direction positive side in the drawing) of the airflow guide member 40 in the first space Z1 constitutes a back space Z1b. However, the front space Z1a and the back space Z1b communicate with each other by a space between the terminal end portion of the guide part 42 and the partition plate 44.

The partition plate 44 is formed with an opening portion 45 through which air passes in the apparatus width direction (X-direction in the drawing) as illustrated in FIG. 5.

The opening portion 45 has a first opening 45a at a first height position, and concretely has the first opening 45a at a height position which is a lower portion of the partition plate 44. An opening position of the first opening 45a is set, for example, on a side closer to a back surface side (back wall 32c side) than a position where the terminal end portion of the guide part 42 is linearly extended toward the side wall 32d to intersect with the partition plate 44 in plan view.

Note that a gap exists between a lower end on the front surface side (front wall 32a side) where the first opening 45a is not provided in the partition plate 44 and the nonwoven fabric 33 below the lower end.

Further, the opening portion 45 has a second opening 45b smaller in dimensions in the vertical direction and the depth direction (Y-direction in the drawing) than the first opening 45a, at a second height position different from the first height position. Concretely, the opening portion 45 has the second opening 45b at a height position that is an upper portion of the partition plate 44. A plurality of the second openings 45b are provided, for example, along the depth direction.

In addition to the partition plate 44, the partition member 43 has a horizontal plate 46. The horizontal plate 46 is a plate-shaped member, and extends in the apparatus width direction (X-direction in the drawing) from the upper end portion of the partition plate 44 along the top plate 31 covering the upper portion of the duct space Z and extends in the depth direction (Y-direction in the drawing). The horizontal plate 46 concretely extends toward the other end portion side (X-direction negative side in the drawing) regarding the apparatus width direction.

Further, as illustrated in FIG. 4, the airflow guide member 40 is set at a position over the cup 23 of the solution treatment apparatus 21 on one end portion side (X-direction positive side in the drawing) located therebelow in plan view, and a center P of the cup 23 is located on the back surface side of the guide part 42 of the airflow guide member 40, namely, in the back space Z1b. The center P of the cup 23 of the solution treatment apparatus 21 on the other end portion side (X-direction negative side in the drawing) is also located close to the back surface in the second space Z2.

Furthermore, at the guide part 42 of the airflow guide member 40, for example, a plurality of the flow parts 42a communicating the front space Z1a and the back space Z1b are formed at a lower end portion of the guide part 42 as illustrated in FIG. 6.

As the nonwoven fabric 33 constituting the lower side of the duct space Z, for example, four nonwoven fabrics are superposed for use. The uppermost nonwoven fabric may be formed in an L shape covering one end portion side near the air inlet 32e and the back face side, and the other three nonwoven fabrics 33 may be formed in rectangles. Note that a lath mesh is sandwiched in the nonwoven fabrics 33 as necessary to provide rigidity so as to maintain the shape and ensure the flatness.

On the lower side of the lowermost nonwoven fabric, the filter 34 is arranged. The filter 34 is, for example, a ULPA filter.

On the lower side of the filter 34, the rectifier plate 35 is arranged. In this embodiment, a perforated metal 35a formed with a number of holes is arranged on the lower side, and spacers 35b are provided at four sides of the perforated metal 35a. Accordingly, a space S is created by the spacers 35b between the lower surface of the filter 34 and the upper surface of the perforated metal 35a.

In the filter apparatus 30, the air from the ducts 7, 8 flows to the duct space Z from the air inlet 32e formed at the one end portion of the duct member 32 in the filter apparatus 30. In this event, regarding the airflow in the horizontal direction, the inflow air flows along the introduction part 41 and the guide part 42 of the airflow guide member 40 to the front space Z1a on the front surface side (front wall 32a side) of the duct space Z. Then, the air collides with the partition plate 44, and part of the air then can flow into the second space Z2 from the first opening 45a and the second openings 45b of the partition plate 44. Further, other part of the air collides with the partition plate 44 and then flows to the back space Z1b on the back surface side (back wall 32c side) of the airflow guide member 40.

On the other hand, the air in the front space Z1a flows from the flow part 42a provided in the guide part 42 of the airflow guide member 40 to above the cup 23 in the back space Z1b.

Then, the air flowing into the front space Z1a of the first space Z1, the air flowing into the back space Z1b, and the air flowing into the second space Z2 pass through and are cleaned by the nonwoven fabrics 33 and the filter 34 on the lower side, and flow from the perforated metal 35a to above the solution treatment apparatus 21 therebelow via the space S at the upper portion in the rectifier plate 35.

Further, as illustrated in FIG. 3 and FIG. 4, the filter apparatus 30 has an air volume adjustment mechanism 50 being a distribution mechanism. The distribution mechanism is a mechanism which distributes the air supplied to the duct space Z from the air inlet 32e formed on the one end portion side in the apparatus width direction being the row direction of the plurality of solution treatment apparatuses 21, to the plurality of solution treatment apparatuses 21.

The air volume adjustment mechanism 50 is a mechanism which variably adjusts the volume of the air flowing from the first space Z1 on the air inlet 32e side in the duct space Z into the second space Z2 adjacent to the first space Z1 in the apparatus width direction. The air volume adjustment mechanism 50 is provided at a position between apparatuses in the plurality of solution treatment apparatuses 21 in plan view. In this embodiment, the air volume adjustment mechanism 50 also includes the above partition member 43, and accordingly the partition member 43 is also provided at the position between the apparatuses in plan view.

Note that the position between the apparatuses is concretely a position between the cup 23 of the solution treatment apparatus 21 on the apparatus width direction one end portion side (X-direction positive side in the drawing) and the cup 23 of the solution treatment apparatus 21 on the apparatus width direction other end portion side (X-direction negative side in the drawing).

The air volume adjustment mechanism 50 has a damper 51 and a rotation shaft 52 as illustrated in FIG. 7.

The damper 51 is a plate-shaped member extending in the depth direction (Y-direction in the drawing), and is concretely a plate-shaped member whose depth direction is the long side direction. The rotation shaft 52 is provided in a manner to extend in the depth direction. For example, the rotation shaft 52 is connected to an end portion in the short side direction of the damper 51. The damper 51 is configured to be rotatable around the center axis of the rotation shaft 52.

The damper 51 is provided in a manner to be able to close the opening portion 45 of the partition plate 44.

Specifically, the damper 51 is provided in a manner to be able to selectively close the first opening 45a and the second openings 45b of the partition plate 44.

For example, the rotation shaft 52 is provided at a third height position between the first height position where the first opening 45a is provided and the second height position where the second opening 45b is provided, and the damper 51 can take the following initial state, first state, and second state.

In the initial state, the damper 51 closes the second openings 45b and opens the first opening 45a.

The first state is a state of being rotated by 90° from the initial state, in which the damper 51 opens both the first opening 45a and the second openings 45b.

The second state is a state of being rotated by 180° from the initial state, in which the damper 51 closes the first opening 45a and opens the second openings 45b.

Note that also in the second state, a gap exists between the tip of the damper 51 and the nonwoven fabrics 33 therebelow.

In the filter apparatus 30, the air flowing into the first space Z1 is supplied to the solution treatment apparatus 21 adjacent to the air inlet 32e side of the air volume adjustment mechanism 50 in plan view, and the air adjusted in inflow volume by the air volume adjustment mechanism 50 and flowing into the second space Z2 is supplied to the solution treatment apparatus 21 adjacent to a side of the air volume adjustment mechanism 50 opposite to the air inlet 32e side in plan view.

Further, the rotation shaft 52 extends to the outside of the duct space

Z in the depth direction (Y-direction in the drawing) as illustrated in FIG. 4. For example, the rotation shaft 52 is provided in a manner to extend to the outside on the front surface side of the duct member 32. A portion of the rotation shaft 52 extending to the outside of the duct space Z is connected to a drive mechanism 53 which drives the rotation of the rotation shaft 52. The drive mechanism 53 has a drive source (not illustrated) such as a motor which generates a driving force for rotating the rotation shaft around the axis of the rotation shaft 52. The rotation of the rotation shaft 52 causes the damper 51 to rotate around the rotation shaft 52.

The drive mechanism 53 is controlled by the control unit M. Concretely, the drive mechanism 53 is controlled by the control unit M according to information on the air volume of each solution treatment apparatus 21 to which the filter apparatus 30 supplies clean air. The information on the air volume is based on the detection result by the air volume sensor 26. Further, the information on the air volume is an example of treatment environment information being information related to the treatment environment of the solution treatment apparatus 21.

### Control Example 1

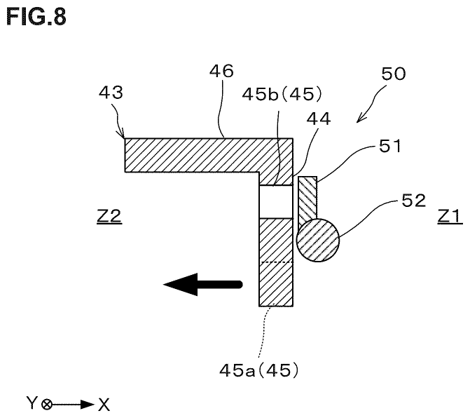

Next, a control example of the filter apparatus 30 will be explained using FIG. 8 to FIG. 10.

First, the control unit M controls the drive mechanism 53 to bring the damper 51 into the initial state as illustrated in FIG. 8 in which the damper 51 closes the second openings 45b and opens the first opening 45a, to supply the air from the first space Z1 to the second space Z2 via the first opening 45a but not to supply the air to the second space Z2 via the second openings 45b.

In this state, the flow rate of the air to be supplied from the filter apparatus 30 is detected by the corresponding air volume sensor 26 for each solution treatment apparatus 21.

When the supply air volume to the solution treatment apparatus 21 on the one end portion side (namely, the supply air volume to the solution treatment apparatus 21 close to the air inlet 32e) and the supply air volume to the solution treatment apparatus 21 on the other end portion side (namely, the supply air volume to the solution treatment apparatus 21 far from the air inlet 32e) are equal as a result of the detection (concretely, when an air volume difference falls within a predetermined range), the control unit M causes the damper 51 to maintain the initial state.

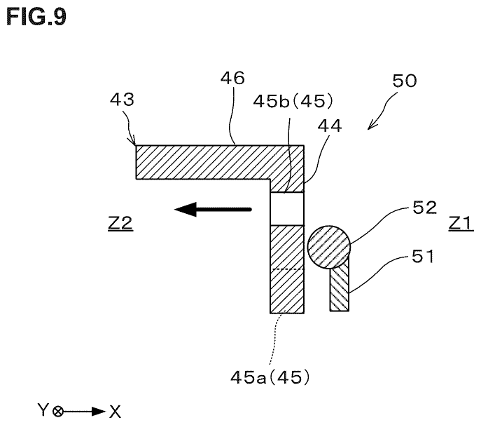

Besides, when the supply air volume to the solution treatment apparatus 21 on the other end portion side (namely, the supply air volume to the solution treatment apparatus 21 far from the air inlet 32e) is larger than the supply air volume to the solution treatment apparatus 21 on the one end portion side (namely, the supply air volume to the solution treatment apparatus 21 close to the air inlet 32e) (concretely, when the air volume difference exceeds a predetermined threshold value) as the result of the detection, the control unit M performs control as follows. Specifically, the control unit M controls the air volume adjustment mechanism 50 so that the air volume to be supplied to the far solution treatment apparatus 21 becomes small. More specifically, the control unit M controls the drive mechanism 53 to bring the damper 51 into the second state as illustrated in FIG. 9, in which the air from the first space Z1 is supplied to the second space Z2 via the second openings 45b but is not supplied to the second space Z2 via the first opening 45a. The total sum of opening areas of the second openings 45b is smaller than the opening area of the first opening 45a. Therefore, the damper 51 is brought into the second state, whereby the flow rate of the air flowing into the second space Z2 is smaller than that in the initial state. Accordingly, the air volume to be supplied to the far solution treatment apparatus 21 from the second space Z2 can be decreased.

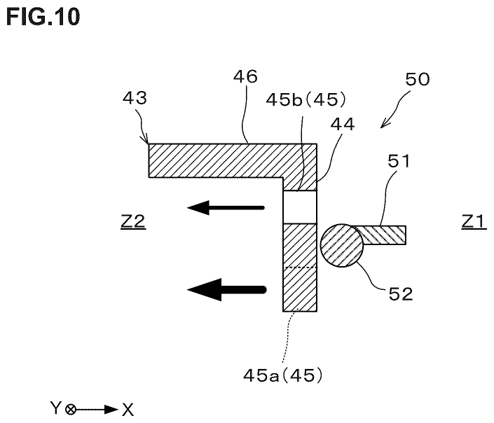

On the other hand, when the supply air volume to the solution treatment apparatus 21 on the other end portion side (namely, the supply air volume to the solution treatment apparatus 21 far from the air inlet 32e) is smaller than the supply air volume to the solution treatment apparatus 21 on the one end portion side (namely, the supply air volume to the solution treatment apparatus 21 close to the air inlet 32e) (concretely, when the air volume difference is below the predetermined threshold value) as the result of the detection, the control unit M performs control as follows. Specifically, the control unit M controls the air volume adjustment mechanism 50 so that the air volume to be supplied to the far solution treatment apparatus 21 becomes large. More specifically, the control unit M controls the drive mechanism 53 to cause the damper 51 into the first state as illustrated in FIG. 10, in which the air from the first space Z1 is supplied to the second space Z2 via both the first opening 45a and the second openings 45b. Accordingly, the air volume to be supplied to the far solution treatment apparatus 21 from the second space Z2 can be increased.

### Control Example 2

If a desired result cannot be obtained even when performing the control as in Control example 1, the angle of the damper 51 may be changed step-wise to obtain the desired result.

For example, in the case where the supply air volume to the solution treatment apparatus 21 far from the air inlet 32e becomes too small when the control is performed as in Control example 1 to bring the damper 51 into the second state, the control unit M may decrease the angle of the damper 51 from 180° step-wise (for example, by 10° or the like) until the air volume detected by the corresponding air volume sensor 26 falls within a predetermined range.

Besides, in the case where the supply air volume to the solution treatment apparatus 21 far from the air inlet 32e becomes too large when the control is performed as in Control example 1 to bring the damper 51 into the first state, the control unit M may decrease or increase the angle of the damper 51 from 90° step-wise (for example, by 10° or the like) until the air volume detected by the corresponding air volume sensor 26 falls within the predetermined range.

In these cases, the control unit M may identify the angle of the damper 51 at which an air volume closer to a target value can be obtained by changing the angle more finely (for example, by 5° or the like) around the angle of the damper 51 when the air volume falls within the predetermined range. Further, in this case, the finer angle change and the identification of the angle of the damper 51 may be repeated.

Note that in the case where the supply air volume to the solution treatment apparatus 21 far from the air inlet 32e is still small even if the control is performed as in Control example 1 to bring the damper 51 into the first state or in the case where the supply air volume to the solution treatment apparatus 21 far from the air inlet 32e is still large even if the damper 51 is brought into the second state, an error may be reported via a report part (not illustrated).

### Effects Relating to the Structure of the Filter Apparatus 30

As explained above, the filter apparatus 30 has the filter 34 installed above the plurality of solution treatment apparatuses 21 arranged in a row, and the air inlet 32e is formed on the one end portion side in the row direction of the solution treatment apparatuses 21 in the duct space Z formed above the filter 34. Further, the filter apparatus 30 has the air volume adjustment mechanism 50 which variably adjusts the volume of the air flowing from the first space Z1 on the air inlet 32e side in the duct space Z into the second space Z2 adjacent to the first space Z1 in the row direction. Therefore, the difference between the air volume to be supplied to one solution treatment apparatus 21 via the first space Z1 and the filter 34 and the air volume to be supplied to the other solution treatment apparatus 21 via the second space Z2 and the filter 34 can be adjusted. Accordingly, the difference in treatment results between the one solution treatment apparatus 21 and the other solution treatment apparatus 21 which have the same configuration and are arranged in a row can be adjusted. Specifically, for example, it is possible to suppress the variation in the treatment results between the one solution treatment apparatus 21 and the other solution treatment apparatus 21. Note that a difference may be intentionally made to occur in the treatment results between the one solution treatment apparatus 21 and the other solution treatment apparatus 21. In other words, the air volume adjustment mechanism 50 may adjust the volume of the air flowing into the second space Z2 so that the difference in the treatment results between the one solution treatment apparatus 21 and the other solution treatment apparatus 21 becomes the desired one.

Incidentally, a flow velocity may become higher at a portion directly under the air volume adjustment mechanism 50 than at the other portion, namely, a strong downflow may be locally formed. In the filter apparatus 30, the position where the air volume adjustment mechanism 50 is provided is a position between the apparatuses in the plurality of solution treatment apparatuses 21 arranged in a row in plan view. Therefore, even if the strong downflow is formed at the portion directly under the air volume adjustment mechanism 50, it is possible to suppress the strong downflow from locally colliding with the solution treatment apparatus 21 (concretely, the wafer in its cup 23). Accordingly, it is possible to suppress the loss of uniformity, in the treatment results of the solution treatment apparatus 21 within the wafer, caused by the strong downflow directly under the air volume adjustment mechanism 50.

Further, the horizontal plate 46 is provided in this embodiment. The horizontal plate 46 is the plate-shaped member as explained above, and extends in the row direction of the solution treatment apparatuses 21 from the upper end portion of the partition plate 44 and extends along the top plate 31 covering the upper portion of the duct space Z in the depth direction (Y-direction in the drawing) intersecting with (concretely, orthogonal to) the row direction. Therefore, the pressure loss in a gap between the horizontal plate 46 and the top plate 31 is large so that the air is less likely to flow through the gap. Accordingly, it is possible to suppress the deflection of the top plate 31 due to the air flowing through the gap. Further, it is possible to suppress the difficulty in adjusting the volume of air flowing into the second space Z2 caused by the deflection of the top plate 31.

### Effects Relating to the Control in this Embodiment

In the filter apparatus 30 according to this embodiment, the control unit M which controls the above air volume adjustment mechanism 50 as the distribution mechanism controls the air volume adjustment mechanism 50 according to the treatment environment information (concretely, the information on the air volume) of each of the plurality of solution treatment apparatuses. Therefore, it is possible to adjust the difference between apparatuses in the air volumes to be supplied to the solution treatment apparatuses 21 which have the same configuration and are arranged in a row. Accordingly, it is possible to adjust the difference between apparatuses in treatment results. For example, it is possible to suppress the variation in treatment results between the solution treatment apparatuses 21 which have the same configuration and are arranged in a row. Note that a difference may be intentionally made to occur in treatment results between the solution treatment apparatuses 21 which have the same configuration and are arranged in a row.

### Other Examples of the Damper 51 and the Partition Plate 44

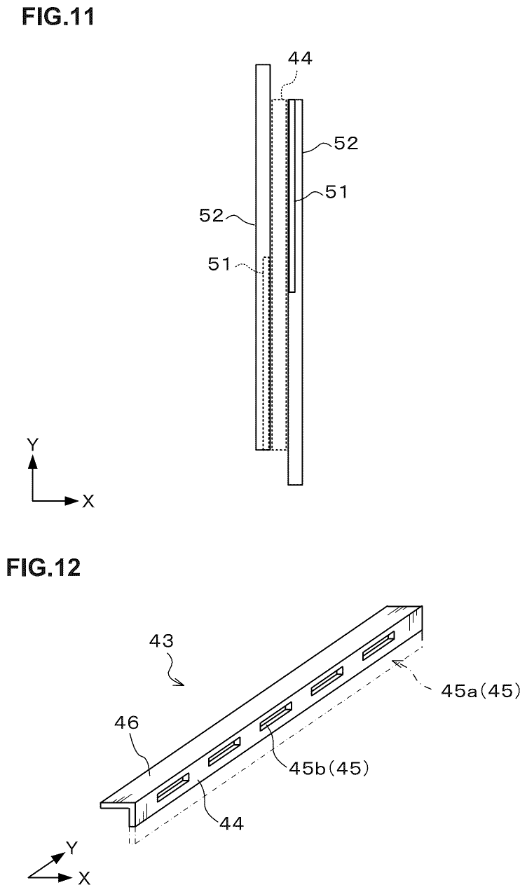

FIG. 11 is a top view for explaining another example of the damper 51 of the air volume adjustment mechanism 50. FIG. 12 is a perspective view for explaining another example of the partition member 43.

As illustrated in FIG. 11, the damper 51 of the air volume adjustment mechanism 50 may be divided into a plurality of (two in the example of the drawing) along the depth direction (Y-direction in the drawing), and the dampers 51 may be configured to be mutually independently rotatable around the center axes of the rotation shafts 52. In this example, one damper 51 and its corresponding rotation shaft 52 are provided on the one end portion side (X-direction positive side in the drawing) of the partition plate 44, and the other damper 51 and its corresponding rotation shaft 52 are provided on the other end portion side (X-direction negative side in the drawing) of the partition plate 44.

The provision of the dampers 51 as above makes it possible to more finely adjust the volume of air flowing into the second space Z2 by the air volume adjustment mechanism 50.

Note that, in this case, the volume of air flowing into the second space Z2 may be adjusted using only one of the damper 51 on the one end portion side (X-direction positive side in the drawing) of the partition plate 44 and the damper 51 on the other end portion side (X-direction negative side in the drawing) of the partition plate 44, or the volume of the air may be adjusted using both of them.

In the example of FIG. 5, the first opening 45a of the partition plate 44 has a shape as if made by notching the back surface side (Y-direction positive side in the drawing) of the lower portion of the partition plate 44. The first opening 45a of the partition plate 44 may have a shape as if made by notching the lower portion of the partition plate 44 entirely in the depth direction (Y-direction in the drawing) as illustrated in FIG. 12.

### Another Example of the Air Volume Adjustment Mechanism 50

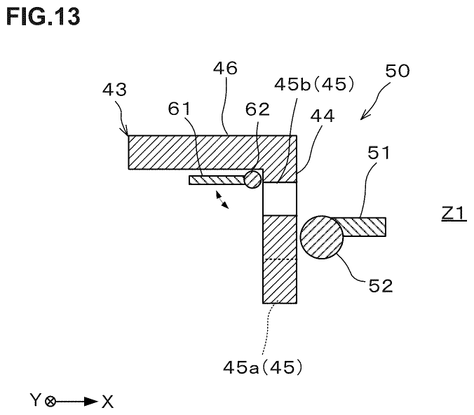

FIG. 13 is a cross-sectional view for explaining another example of the air volume adjustment mechanism 50.

The air volume adjustment mechanism 50 in FIG. 13 has a guide plate 61 which guides the air passing through the opening portion 45 of the partition plate 44.

The guide plate 61 is a plate-shaped member extending in the depth direction (Y-direction in the drawing), and is concretely a plate-shaped member whose depth direction is the long side direction. Further, the guide plate 61 is configured to be rotatable around the center axis of a rotation shaft 62. The rotation shaft 62 is provided to extend in the depth direction (Y-direction in the drawing). The rotation shaft 62 is connected to an end portion in the short side direction of the guide plate 61. Further, the rotation shaft 62 is connected to a drive mechanism (not illustrated) which drives the rotation of the rotation shaft 62. The drive mechanism has a drive source such as a motor which generates a driving force for moving the rotation shaft 62 around the axis of the rotation shaft 62.

The above guide plate 61 is provided on the other end portion side (X-direction negative side in the drawing) of the partition plate 44. The rotation shaft 62 is provided on an upper portion on the other end portion side (X-direction negative side in the drawing) of the partition plate 44.

The guide plate 61 is rotated to be inclined on its tip side from the horizontal and thereby can guide diagonally downward the air passing through the second openings 45b of the partition plate 44. Therefore, it is possible to increase the flow velocity of the air passing through the second openings 45b of the partition plate 44 to be supplied to the solution treatment apparatus 21 on the other end portion side (X-direction negative side in the drawing).

This guide plate 61 is useful as a measure in the case where the supply flow velocity to the solution treatment apparatus 21 on the other end portion side (X-direction negative side in the drawing) cannot be made sufficiently high even if the damper 51 is brought into the initial state.

Further, this guide plate 61 can also be used as follows. Specifically, it is possible that the guide plate 61 closes the second openings 45b and the damper 51 adjusts the air volume of the airflow passing through the first opening 45a.

### The Number of Sensors 26 Arranged

A plurality of the air volume sensors 26 may be provided for each solution treatment apparatus 21.

### Other Examples of the Arrangement of the Air Volume Sensor 26 and the Control of the Air Volume Adjustment Mechanism 50

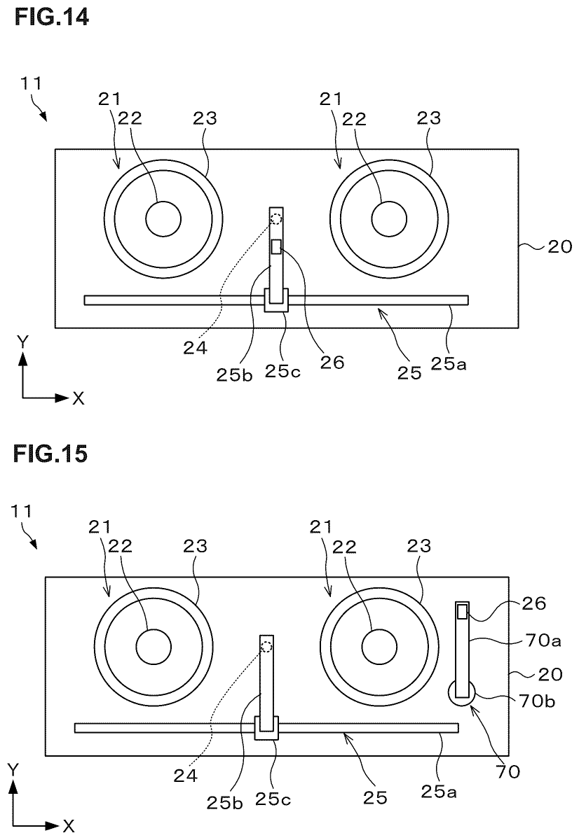

FIG. 14 and FIG. 15 are explanatory views illustrating other examples of the arrangement of the air volume sensor 26.

As illustrated in FIG. 14, the air volume sensor 26 may be provided on an upper surface of the arm 25b of the moving mechanism 25 of the nozzle 24. In this case, the moving mechanism 25 of the nozzle 24 also serves as the moving mechanism of the air volume sensor 26 so that the air volume sensor 26 is movable in the horizontal direction by the moving mechanism 25.

Further, as illustrated in FIG. 15, a moving mechanism 70 of the air volume sensor 26 may be provided separately from the moving mechanism 25 of the nozzle 24. The moving mechanism 70 has, for example, an arm 70a and a drive mechanism 70b.

To an upper surface of the arm 70a, the air volume sensor 26 is attached. Concretely, a base end portion of the arm 70a is connected to the drive mechanism 70b, and the air volume sensor 26 is attached to an upper surface of a tip end portion of the arm 70a. The arm 70a is rotatable around the vertical axis passing through the base end portion by the drive mechanism 70b. The drive mechanism 70b has a drive source (not illustrated) such as a motor which generates a driving force for the above rotation of the arm 70a. The rotation of the arm 70a around the vertical axis by the drive mechanism 70b causes the air volume sensor 26 to move in the horizontal direction, concretely, rotate around the vertical axis.

In the case where the air volume sensor 26 is configured to be movable in the horizontal direction as in the configuration illustrated in FIG. 14 and FIG. 15, it is possible to perform detection by the air volume sensor 26 at a plurality of points different from one another above the wafer for each solution treatment apparatus 21.

In this case, the control unit M acquires the information on the air volume detected by the air volume sensor 26 as the treatment environment information for each of the plurality of points for each solution treatment apparatus 21. The control unit M then controls the air volume adjustment mechanism 50 being the distribution mechanism according to the information on the air volume at each of the plurality of points acquired for each solution treatment apparatus 21. For example, the control unit M calculates an average value of the acquired air volumes for each solution treatment apparatus 21, and controls the air volume adjustment mechanism 50 according to the average value of the air volume of each of the plurality of solution treatment apparatuses 21. More specifically, for example, in the case where the average value of the supply air volume to the solution treatment apparatus 21 on the other end portion side (namely, the supply air volume to the solution treatment apparatus 21 far from the air inlet 32e) is larger the average value of the supply air volume to the solution treatment apparatus 21 on the one end portion side (namely, the supply air volume to the solution treatment apparatus 21 close to the air inlet 32e), the control unit M brings the damper 51 into the second state.

Note that the control unit M may control the air volume adjustment mechanism 50 so that the uniformity within the wafer of the air volume in each solution treatment apparatus 21 is improved, according to the information on the air volume at each of the plurality of points acquired for each solution treatment apparatus 21.

### Another Example 1 of the Treatment Environment Information

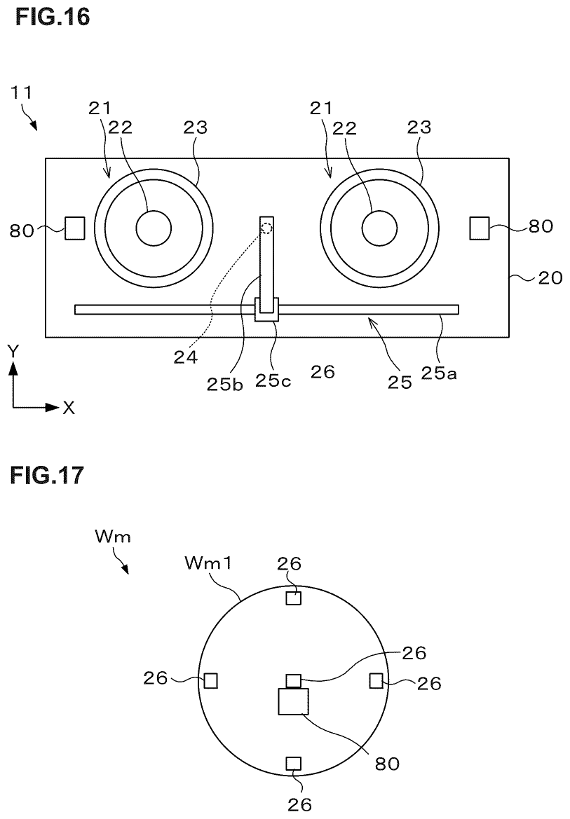

FIG. 16 is an explanatory view illustrating another example of the solution treatment module 11.

In the above, the treatment environment information is the information on the air volume. The treatment environment information may be at least any one of the temperature and the humidity. In this case, in the solution treatment module 11, for example, a temperature and humidity sensor 80 which detects both temperature and humidity is provided for each solution treatment apparatus 21 as illustrated in FIG. 16. The temperature and humidity sensor 80 is relatively large so that if the temperature and humidity sensor 80 overlaps in plan view with the wafer in the corresponding solution treatment apparatus 21, the air from the filter apparatus 30 may be blocked by the temperature and humidity sensor 80. Therefore, the temperature and humidity sensor 80 is provided, for example, at a position where it does not overlap in plan view with the wafer in the corresponding solution treatment apparatus 21. The detection result by the temperature and humidity sensor 80 at the position where it does not overlap in plan view with the wafer in the solution treatment apparatus 21 may be calibrated based on the correspondence between the detection result by the temperature and humidity sensor 80 at the position acquired in advance and the detection result by the temperature and humidity sensor above the spin chuck 22.

In this case, for example, the control unit M controls the drive mechanism 53 to bring the damper 51 into the initial state and, in this state, causes the corresponding temperature and humidity sensor 80 to detect the temperature and the humidity in the solution treatment apparatus 21 for each solution treatment apparatus 21.

In the case where the detected temperature and the detected humidity are equal between the solution treatment apparatus 21 close to the air inlet 32e and the solution treatment apparatus 21 far from the air inlet 32e as a result of the detection, the control unit M causes the damper 51 to maintain the initial state.

Besides, in the case where the temperature is higher or the humidity is lower in the solution treatment apparatus 21 far from the air inlet 32e than in the solution treatment apparatus 21 close to the air inlet 32e as the result of the detection, the control unit M brings the damper 51 into the first state so as to increase the inflow volume into the second space Z2. The air supplied from the second space Z2 to the solution treatment apparatus 21 tends to stay in the duct space Z for longer time than the air supplied from the first space Z1 to the solution treatment apparatus 21, and becomes high in temperature by a heat generating member (for example, an electrical device) in the duct space Z. By increasing the inflow volume into the second space Z2 as explained above, the air supplied from the second space Z2 to the solution treatment apparatus 21 becomes short in time staying in the duct space Z and low in temperature. Supplying the air at low temperature from the second space Z2 to the solution treatment apparatus 21 far from the air inlet 32e makes it possible to decrease the temperature and increase the humidity in the far solution treatment apparatus 21.

On the other hand, in the case where the temperature is lower or the humidity is higher in the solution treatment apparatus 21 far from the air inlet 32e than in the solution treatment apparatus 21 close to the air inlet 32e as the result of the detection, the control unit M brings the damper 51 into the second state so as to decrease the inflow volume into the second space Z2. Thus, the air supplied from the second space Z2 to the solution treatment apparatus 21 stays for long time in the duct space Z and becomes high in temperature. Supplying the air at high temperature from the second space Z2 to the solution treatment apparatus 21 far from the air inlet 32e makes it possible to increase the temperature and decrease the humidity in the far solution treatment apparatus 21.

Note that in place of the temperature and humidity sensor 80 which detects both the temperature and the humidity, a temperature sensor which detects only the temperature or a humidity sensor which detects only the humidity may be provided.

### Other Examples of the Air Volume Sensor 26 and the Temperature and Humidity Sensor 80

FIG. 17 is an explanatory view illustrating an example of a measurement wafer.

As illustrated in FIG. 17, the air volume sensor 26 and the temperature and humidity sensor 80 may be mounted on a measurement wafer Wm as a measurement substrate imitating a product wafer.

The measurement wafer Wm has a main body part Wm1 having the same shape as the product wafer. On an upper surface of the main body part Wm1, the air volume sensor 26 and the temperature and humidity sensor 80 are mounted. Specifically, a plurality of the air volume sensors 26 are provided along the circumferential direction on the upper surface at a peripheral portion of the main body part Wml and one air volume sensor 26 is mounted on the upper surface at a central portion of the main body part Wm1, and one temperature and humidity sensor 80 is mounted on the upper surface at the central portion of the main body part Wm1.

The measurement wafer Wm performs detection, in a state of being mounted on the spin chuck 22, by the air volume sensors 26 and the temperature and humidity sensor 80. The detection results are transmitted to the control unit M via a transmitter (not illustrated) mounted on the measurement wafer Wm.

In this case, the treatment environment information is based on the detection results by the air volume sensors 26 and the temperature and humidity sensor 80 received by the control unit M from the measurement wafer Wm.

### Another Example 2 of the Treatment Environment Information

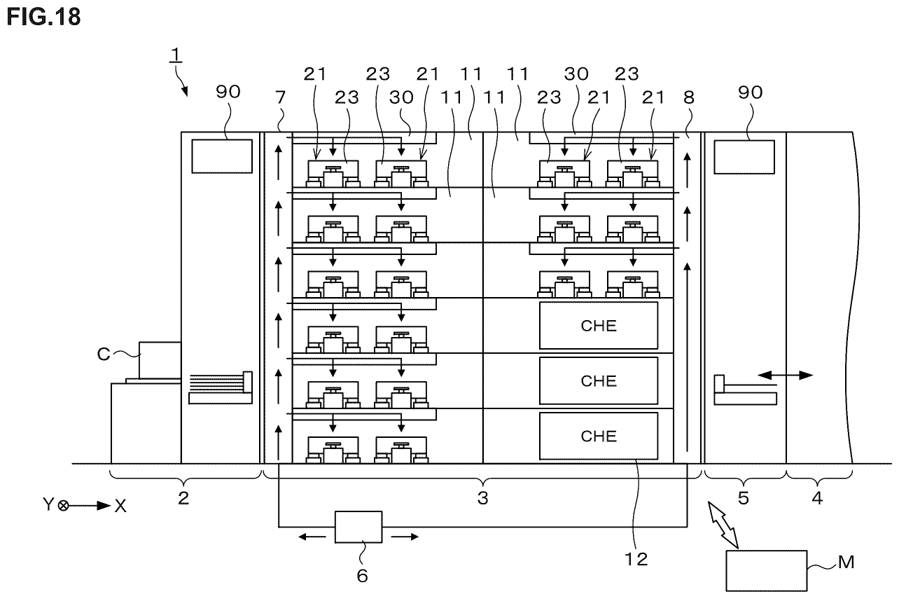

FIG. 18 is an explanatory view illustrating another example of the coating and developing apparatus 1.

The treatment environment information may be the one based on the detection result by an inspection apparatus 90 which inspects the wafer after the treatment by the solution treatment apparatus 21. The inspection apparatus 90 is provided, for example, at least any one of the carrier block 2 and the interface block 5. The inspection apparatus 90 performs detection based on, for example, a captured image of the wafer.

The inspection apparatus 90 measures, for example, the thickness of a coating film on the wafer which is influenced by the air volume of the air supplied from the filter apparatus 30 in the case where the solution treatment apparatus 21 is the coating apparatus.

In this case, for example, the control unit M controls the drive mechanism 53 to bring the damper 51 into the initial state and causes the inspection apparatus 90 to detect the thickness of the coating film formed on the wafer after the coating treatment by the solution treatment apparatus 21 in this state for each solution treatment apparatus 21.

In the case where the thickness of the coating film is equal between the solution treatment apparatus 21 close to the air inlet 32e and the solution treatment apparatus 21 far from the air inlet 32e as a result of the detection, the control unit M causes the damper 51 to maintain the initial state.

Besides, in the case where the coating film is thicker in the solution treatment apparatus 21 far from the air inlet 32e than in the solution treatment apparatus 21 close to the air inlet 32e as the result of the detection, the control unit M brings the damper 51 into the first state so that the inflow volume into the second space Z2 becomes large to increase the air volume to be supplied from the second space Z2 to the far solution treatment apparatus 21.

On the other hand, in the case where the coating film is thinner in the solution treatment apparatus 21 far from the air inlet 32e than in the solution treatment apparatus 21 close to the air inlet 32e as the result of the detection, the control unit M brings the damper 51 into the second state so that the inflow volume into the second space Z2 becomes small to decrease the air volume to be supplied from the second space Z2 to the far solution treatment apparatus 21.

Note that the angle of the damper 51 may be adjusted in a pattern reverse to that in the above example depending on the kind of the treatment solution. For example, information correlating the kind of the treatment solution and the adjustment mode of the angle of the damper 51 has been stored in a storage (not illustrated), and the adjustment mode of the angle of the damper 51 is decided by the control unit M based on the correlating information.

Further, the inspection apparatus 90 may measure the dimension (CD: Critical Dimension) of the resist pattern after the development that is influenced by the temperature in the solution treatment apparatus 21 in the case where the solution treatment apparatus 21 is the developing apparatus.

In this case, for example, the control unit M controls the drive mechanism 53 to bring the damper 51 into the initial state and causes the inspection apparatus 90 to detect the dimension of the resist pattern formed on the wafer after the developing treatment by the solution treatment apparatus 21 in this state for each solution treatment apparatus 21.

In the case where the dimension of the resist pattern is equal between the solution treatment apparatus 21 close to the air inlet 32e and the solution treatment apparatus 21 far from the air inlet 32e as a result of the detection, the control unit M causes the damper 51 to maintain the initial state. Besides, in the case where the dimension of the resist pattern is

larger in the solution treatment apparatus 21 far from the air inlet 32e than in the solution treatment apparatus 21 close to the air inlet 32e as the result of the detection, the control unit M brings the damper 51 into the first state so that the inflow volume into the second space Z2 becomes large to increase the air volume to be supplied from the second space Z2 to the far solution treatment apparatus 21.

On the other hand, in the case where the dimension of the resist pattern is smaller in the solution treatment apparatus 21 far from the air inlet 32e than in the solution treatment apparatus 21 close to the air inlet 32e as the result of the detection, the control unit M brings the damper 51 into the second state so that the inflow volume into the second space Z2 becomes small to decrease the air volume to be supplied from the second space Z2 to the far solution treatment apparatus 21.

Note that the angle of the damper 51 may be adjusted in a pattern reverse to that in the above example depending on the kind of the treatment solution. For example, information correlating the kind of the treatment solution and the adjustment mode of the angle of the damper 51 has been stored in a storage (not illustrated), and the adjustment mode of the angle of the damper 51 is decided by the control unit M based on the correlating information.

### Other Modifications

In the case where the control unit M does not control the air volume adjustment mechanism 50, the drive mechanism 53 may be omitted and an operator may manually rotate the damper 51 of the air volume adjustment mechanism 50.

The inspection apparatus 90 may be installed in another semiconductor manufacturing apparatus which transfers the wafer to/from the coating and developing apparatus 1 on a carrier-by-carrier basis.

The embodiments disclosed herein are examples in all respects and should not be considered to be restrictive. Various omissions, substitutions, and changes may be made in the embodiments without departing from the scope and the spirit of the attached claims. For example, configuration requirements of the above embodiments can be arbitrarily combined. From the arbitrary combination, the operations and effects about the configuration requirements relating to the combination can be obtained as a matter of course, and other operations and other effects apparent to those skilled in the art are obtained from the description herein.

Besides, the effects explained herein are merely explanatory or illustrative in all respects and not restrictive. In other words, the technique relating to this disclosure can offer other effects apparent to those skilled in the art from the description herein in addition to or in place of the above effects.

Note that the following configuration examples also belong to the technical scope of this disclosure.

(1) A filter apparatus for a substrate treatment apparatus, the filter apparatus having a filter installed above a plurality of substrate treatment apparatuses arranged in a row,
the filter apparatus including:
an air inlet formed on one end portion side in a row direction of the substrate treatment apparatuses in a duct space formed above the filter; and
an air volume adjustment mechanism configured to variably adjust a volume of air flowing from a first space on the air inlet side in the duct space into a second space adjacent to the first space in the row direction,
the air volume adjustment mechanism being provided at a position between apparatuses in the plurality of substrate treatment apparatuses in plan view.

(2) The filter apparatus for a substrate treatment apparatus according to the (1), wherein:
the air volume adjustment mechanism includes a plate-shaped damper extending in a depth direction intersecting with the row direction in a horizontal plane; and
the damper is configured to be rotatable around a rotation axis extending in the depth direction.

(3) The filter apparatus for a substrate treatment apparatus according to the (2), wherein
the rotation shaft is provided at an end portion in a short side direction of the damper intersecting with the depth direction.

(4) The filter apparatus for a substrate treatment apparatus according to the (2) or (3), wherein
the rotation shaft extends to an outside of the duct space in the depth direction.

(5) The filter apparatus for a substrate treatment apparatus according to any one of the (2) to (4), wherein:
the air volume adjustment mechanism further includes a partition plate configured to vertically partition at least an upper portion of the duct space;
the partition plate has an opening portion through which air passes in the row direction; and
the damper is provided to be able to close the opening portion of the partition plate.

(6) The filter apparatus for a substrate treatment apparatus according to the (5), further including
a top plate configured to cover an upper portion of the duct space, wherein
the air volume adjustment mechanism further has a horizontal plate which extends from an upper end portion of the partition plate along the top plate in the row direction and extends in the depth direction.

(7) The filter apparatus for a substrate treatment apparatus according to the (5) or (6) wherein:
the opening portion of the partition plate
   has a first opening at a first height position, and
   has a second opening smaller than the first opening in dimensions in the vertical direction and the depth direction, at a second height position different from the first height position;
the rotation shaft of the damper is provided at a third height position between the first height position and the second height position; and
the damper
   closes the second opening and opens the first opening, in an initial state,
   opens the first opening and the second opening, in a state of being rotated by 90° from the initial state, and
   closes the first opening and opens the second opening, in a state of being rotated by 180° from the initial state.

(8) A clean air supply method to a substrate treatment apparatus using a filter apparatus having a filter installed above a plurality of substrate treatment apparatuses arranged in a row,
the filter apparatus including:
   an air inlet formed on one end portion side in a row direction of the substrate treatment apparatuses in a duct space formed above the filter; and
   an air volume adjustment mechanism configured to variably adjust a volume of air flowing from a first space on the air inlet side in the duct space into a second space adjacent to the first space in the row direction,
   the air volume adjustment mechanism being provided at a position between apparatuses in the plurality of substrate treatment apparatuses in plan view,
the method including
supplying air flowing into the first space to the substrate treatment apparatus adjacent to the air inlet side of the air volume adjustment mechanism in plan view, and supplying air adjusted in inflow volume by the air volume adjustment mechanism and flowing into the second space to the substrate treatment apparatus adjacent to a side of the air volume adjustment mechanism opposite to the air inlet in plan view.

According to this disclosure, it is possible to adjust a difference in treatment results between substrate treatment apparatuses in a case where a plurality of substrate treatment apparatuses are arranged in a row and clean air is supplied to each substrate treatment apparatus from a filter apparatus common between the substrate treatment apparatuses.

What is claimed is:

1. A filter apparatus for a substrate treatment apparatus, the filter apparatus having a filter installed above a plurality of substrate treatment apparatuses arranged in a row,
the filter apparatus comprising:
an air inlet formed on one end portion side in a row direction of the substrate treatment apparatuses in a duct space formed above the filter; and
an air volume adjustment mechanism configured to variably adjust a volume of air flowing from a first space on the air inlet side in the duct space into a second space adjacent to the first space in the row direction, the air volume adjustment mechanism being provided at a position between apparatuses in the plurality of substrate treatment apparatuses in plan view.

2. The filter apparatus for a substrate treatment apparatus according to claim 1, wherein:
the air volume adjustment mechanism includes a plate-shaped damper extending in a depth direction intersecting with the row direction in a horizontal plane; and
the damper is configured to be rotatable around a rotation axis extending in the depth direction.

3. The filter apparatus for a substrate treatment apparatus according to claim 2, wherein
the rotation shaft is provided at an end portion in a short side direction of the damper intersecting with the depth direction.

4. The filter apparatus for a substrate treatment apparatus according to claim 2, wherein
the rotation shaft extends to an outside of the duct space in the depth direction.

5. The filter apparatus for a substrate treatment apparatus according to claim 3, wherein
the rotation shaft extends to an outside of the duct space in the depth direction.

6. The filter apparatus for a substrate treatment apparatus according to claim 2, wherein:
the air volume adjustment mechanism further comprises a partition plate configured to vertically partition at least an upper portion of the duct space;
the partition plate has an opening portion through which air passes in the row direction; and
the damper is provided to be able to close the opening portion of the partition plate.

7. The filter apparatus for a substrate treatment apparatus according to claim 3, wherein:
the air volume adjustment mechanism further comprises a partition plate configured to vertically partition at least an upper portion of the duct space;
the partition plate has an opening portion through which air passes in the row direction; and
the damper is provided to be able to close the opening portion of the partition plate.

8. The filter apparatus for a substrate treatment apparatus according to claim 6, further comprising
a top plate configured to cover an upper portion of the duct space, wherein
the air volume adjustment mechanism further has a horizontal plate which extends from an upper end portion of the partition plate along the top plate in the row direction and extends in the depth direction.

9. The filter apparatus for a substrate treatment apparatus according to claim 6, wherein:
the opening portion of the partition plate
has a first opening at a first height position, and
has a second opening smaller than the first opening in dimensions in the vertical direction and the depth direction, at a second height position different from the first height position;
the rotation shaft of the damper is provided at a third height position between the first height position and the second height position; and
the damper
closes the second opening and opens the first opening, in an initial state,
opens the first opening and the second opening, in a state of being rotated by 90° from the initial state, and
closes the first opening and opens the second opening, in a state of being rotated by 180° from the initial state.

10. A clean air supply method to a substrate treatment apparatus using a filter apparatus having a filter installed above a plurality of substrate treatment apparatuses arranged in a row,
the filter apparatus comprising:
an air inlet formed on one end portion side in a row direction of the substrate treatment apparatuses in a duct space formed above the filter; and
an air volume adjustment mechanism configured to variably adjust a volume of air flowing from a first space on the air inlet side in the duct space into a second space adjacent to the first space in the row direction,
the air volume adjustment mechanism being provided at a position between apparatuses in the plurality of substrate treatment apparatuses in plan view,
the method comprising
supplying air flowing into the first space to the substrate treatment apparatus adjacent to the air inlet side of the air volume adjustment mechanism in plan view, and supplying air adjusted in inflow volume by the air volume adjustment mechanism and flowing into the second space to the substrate treatment apparatus adjacent to a side of the air volume adjustment mechanism opposite to the air inlet in plan view.
